(19) United States
(12) Patent Application Publication
(10) Pub. No.: US 2008/0276989 A1
(43) Pub. Date: Nov. 13, 2008

(54) METHOD OF HYBRID STACKED FLIP CHIP FOR A SOLAR CELL

(76) Inventors: Liann-Be Chang, Dasi Township (TW); Yu-Lin Lee, Jiali Township (TW)

Correspondence Address: Alan D. Kamrath;Kamrath & Associates, P.A., Suite 245, 4825 Olson Memorial Highway, Golden Valley, MN, 55422, US

(21) Appl. No.: 11/746,698

(22) Filed: May 10, 2007

(51) Int. Cl. H01L 31/00

(52) U.S. Cl. 136/261

(57) ABSTRACT

A method of hybrid stacked Flip Chip for a solar cell onto which semiconductor layers of different materials are stacked in the Flip-Chip technology to solve the problem of lattices mismatch between the layers for further increase of the efficiency of solar cell.

### BACKGROUND OF THE INVENTION

1. Field of the Invention

This invention relates to a method and technology of hybrid stacked Flip Chip for a solar cell and particularly to that of manufacturing a simple and higher efficient solar cell.

2. Description of Related Art

As shown in FIG. 4A, the solar cell comprises a substrate 60 of silicon (Si), germanium (Ge), or Si/Ge. On the substrate 60, a P-N Junction semiconductor layer 61, such as Si/SiGe, that may absorb a long wavelength (e.g. infrared rays) is formed. It has efficient of only 15% around.

A compound solar cell is formed by a compound semiconductor on a substrate to absorb medium wavelength solar spectrum. Owing to a direct bandgap, it is higher efficient and absorbs the correspondent wavelength of 25% around. As shown in FIG. 4B, the solar cell comprises a substrate 70 of GaAs, AlGaAs, InGaP or GaP. On the substrate 70, a P-N junction semiconductor layer 71, such as GaAs/AlGaAs, GaAs/lnGaP, GaP/GaP, GaAs/AlInGaP, and GaAs/AlGaAs . . . etc, that may absorb a medium wavelength (e.g. visible rays) is formed.

As shown in FIG. 4C, the solar cell comprises a substrate 80 of Al₂O₃ sapphire, silicon carbide, or ZnO. On the substrate 80, a P-N junction semiconductor layer 81, such as GaN/AlGaN, GaN/InGaN and InGaN/AlGaN that may absorb a short wavelength (e.g. ultraviolet rays) is formed.

However, each solar cells mentioned above may absorb only the correspondent long wavelength (as shown in FIG. 4A), medium wavelength (as shown in FIG. 4B), or the short wavelength (as shown in FIG. 4C), respectively.

Thus, recently a tandem cell is provided, in which materials of different bandgaps are stacked into the cell of multiple junctions.

As shown in FIG. 5A, the solar cell comprises a substrate 60 of Si, Ge, or Si/Ge. On the substrate 60, a P-N junction semiconductor layer 61, such as Si and SiGe, that may absorb the long wavelength is stacked so as to absorb rays of light, and an tunnel junction 10 is formed on the layer 61. On the tunnel junction 10, a P-N junction semiconductor layer 71, such as GaAs, that may absorb the medium wavelength is then stacked, and an tunnel junction 10 is formed on the layer 71. On the tunnel junction 10, a P-N junction semiconductor layer 72, such as AlGaAs and InGaP, which may absorb the medium wavelength is then stacked

As shown in FIG. 5B, the solar cell comprises a substrate 70 of GaAs, As, or GaP. On the substrate 70, a P-N junction semiconductor layer 71, such as GaAs, that may absorb the medium wavelength is then stacked, and tunnel junction 10 is formed on the layer 71. On the tunnel junction 10, a P-N junction semiconductor layer 72, such as AlGaAs and InGaP, which may absorb the medium wavelength is then stacked.

However, Si/SiGe, GaN/AlGaN, and GaAs/AlGaAs used for the semiconductors are quite different, so the semiconductor epitaxy when being formed is easily polluted alternately with each other, and lattice matching is also very different.

Consequently, because of the technical defects of described above, the applicant keeps on carving unflaggingly through wholehearted experience and research to develop the present invention, which can effectively improve the defects described above.

### SUMMARY OF THE INVENTION

This invention relates to a method of hybrid stacked Flip Chip for a solar cell, comprising:

step 1 of forming a solar cell with at least one pair P-N junction semiconductor layers and making each P-N junction semiconductor layer could absorb various wavelength of solar spectrum by corresponding to different materials;

step 2 of forming another solar cell with at least one P-N junction semiconductor layers of which the series of materials are different from step 1; and

step 3 of stacking each of the P-N junction semiconductor layers described at step 1 and step 2 in the Flip-Chip technology and stacking in order the P-N junction semiconductor layers from long wavelength to short wavelength.

Thus, the Flip-Chip technology is used in this invention to stack different series solar cell for increase of the efficient of solar cell and solve the problem of lattice mismatch.

### BRIEF DESCRIPTION OF THE DRAWINGS

FIG. 1 is a flow chart of this invention;

FIG. 2A through FIG. 2D are schematic views illustrating embodiments of this invention;

FIG. 3 is a schematic view illustrating a preferred embodiment of this invention;

FIG. 4A through FIG. 4C are schematic views illustrating conventional embodiments; and

FIG. 5A and FIG. 5B are schematic views illustrating another embodiment.

### DETAILED DESCRIPTION OF THE PREFERRED EMBODIMENTS

Now, the present invention will be described more specifically with reference to the following embodiments. It is to be noted that the following descriptions of preferred embodiments of this invention are presented herein for purpose of illustration and description only; it is not intended to be exhaustive or to be limited to the precise form disclosed.

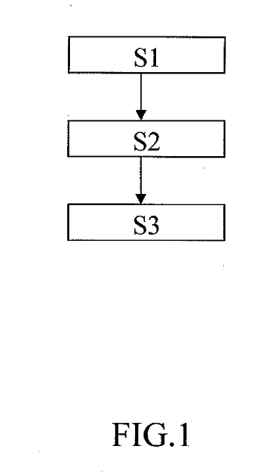

This invention relates to a method of hybrid stacked Flip Chip for a solar cell and is used to stack a solar cell onto on another solar cell in the Flip-Chip technology, as shown in FIG. 1, the method comprising:

step 1 of forming a solar cell with at least one pair P-N junction semiconductor layers and making each P-N junction semiconductor layer could absorb various wavelength of solar spectrum by corresponding to different materials;

step 2 of forming another solar cell with at least one P-N junction semiconductor layers of which the series of materials are different from step 1; and

step 3 of stacking each of the P-N junction semiconductor layers described at step 1 and step 2 in the Flip-Chip technology and stacking in order the P-N junction semiconductor layers from long wavelength to short wavelength.

In the following description, there are figures illustrating embodiments of this invention

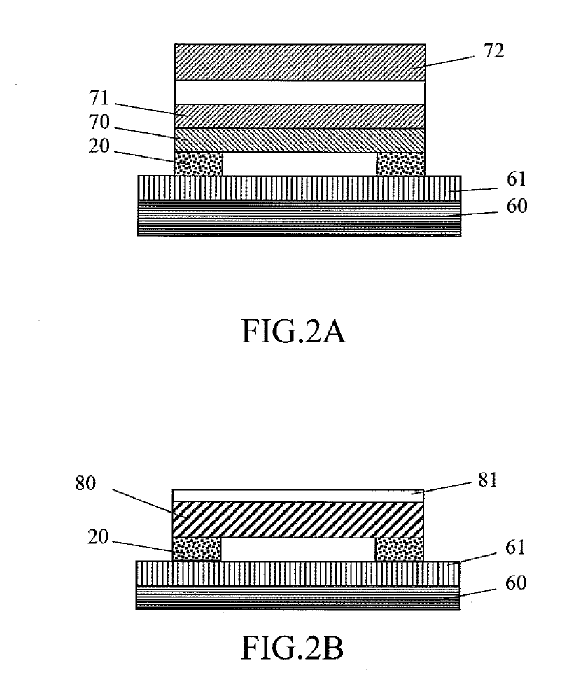

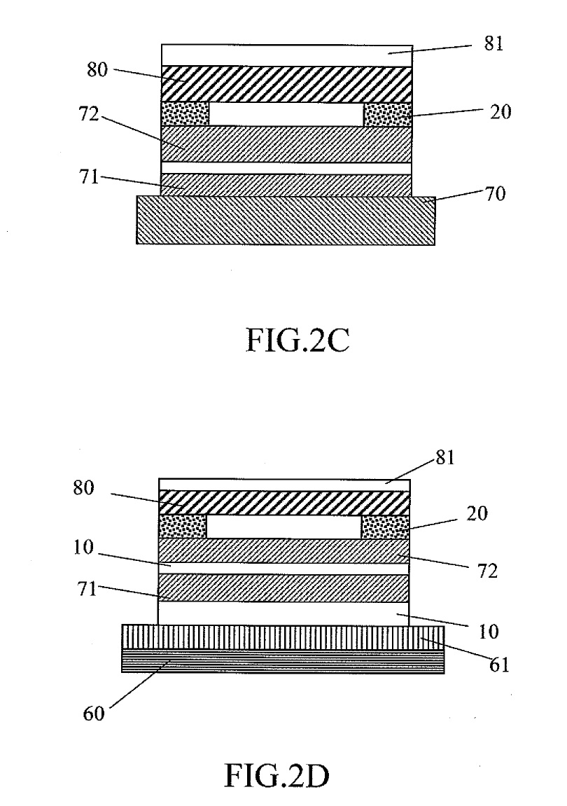

Refer to FIG. 2A illustrating:

a formed P-N junction semiconductor layer 61 of Si and Ge that may absorb long wavelength, and its substrate 60 of Si, Ge, or Si/Ge;

formed P-N junction semiconductor layers 71 and 72 of As, Ga, and P that may absorb medium wavelength, and its substrate 70 of InP or GaAs, or GaP;

in the Flip-Chip technology, the P-N junction semiconductor layers 71 and 72 of As, Ga, and P that may absorb medium wavelength being stacked onto the P-N junction semiconductor layer 61 of Si and Ge that may absorb long wavelength, in which the P-N junction semiconductor layers 71 and 72 of As, Ga, and P that may absorb medium wavelength lie on the substrate 70 of InP, GaAs or GaP;

The series of materials of the P-N junction semiconductor layer 61 of Si and Ge that may absorb long wavelength and those of the P-N junction semiconductor layers 71 and 72 of As, Ga, and P that may absorb medium wavelength being different so that connection bumps 20 may be formed between the two P-N junction semiconductor layers and the two P-N junction semiconductor layers of different materials are combined together in the form of Flip Chip.

Refer to FIG. 2B illustrating:

a formed P-N junction semiconductor layers 61 of Si and Ge that may absorb long wavelength, and its substrate 60 of Si, Ge, or Si/Ge;

a formed P-N junction semiconductor layers 80 of Ga, In, Al an N that may absorb short wavelength, and its transparent substrate 81 of Al₂O₃ sapphire, silicon carbide, or ZnO;

in the Flip-Chip technology, the P-N junction semiconductor layers 80 of Ga, In, Al an N that may absorb short wavelength being stacked onto the P-N junction semiconductor layers 61 of Si and Ge that may absorb long wavelength, in which the transparent substrate 81 of Al₂O₃ sapphire, silicon carbide, or ZnO lies on the P-N junction semiconductor layers 80 of Ga, In, Al an N that may absorb short wavelength;

The series of materials of the P-N junction semiconductor layers 61 of Si and Ge that may absorb long wavelength and those of the P-N junction semiconductor layers 80 of Ga, In, Al an N that may absorb short wavelength being different so that connection bumps 20 may be formed between the two P-N junction semiconductor layers and the two P-N junction semiconductor layers of different materials are combined together in the form of Flip Chip.

Refer to FIG. 2C illustrating:

formed P-N junction semiconductor layers 71 and 72 of As, Ga, and P that may absorb medium wavelength, and its substrate 70 of InP, GaAs or GaP;

a formed P-N junction semiconductor layers 80 of Ga, In, Al an N that may absorb long wavelength, and its transparent substrate 81 of Al₂O₃ sapphire, silicon carbide, or ZnO;

in the Flip-Chip technology, the P-N junction semiconductor layers 80 that may absorb short wavelength being stacked onto the P-N junction semiconductor layers 71 and 72 of As, Ga, and P that may absorb medium wavelength, in which the transparent substrate 81 of Al₂O₃ sapphire, silicon carbide, or ZnO lies on the P-N junction semiconductor layers 80 of Ga, In, Al an N that may absorb short wavelength;

The series of materials of the P-N junction semiconductor layers 71 and 72 of As, Ga, and P that may absorb medium wavelength and those of the P-N junction semiconductor layers 80 of Ga, In, Al an N that may absorb short wavelength being different so that connection bumps 20 may be formed between the two P-N junction semiconductor layers and the two P-N junction semiconductor layers of different materials are combined together in the form of Flip Chip.

Refer to FIG. 2D illustrating:

a substrate 60 of Si, Ge, or Si/Ge on which a P-N junction semiconductor layers 61, such as Si and SiGe, that may absorb the long wavelength is stacked; an tunnel junction 10 being formed on the layer 61, and on the tunnel junction 10, a P-N junction semiconductor layers 71, such as GaAs, that may absorb the medium wavelength; an tunnel junction 10 being again formed on the layer 71, and on the tunnel junction 10, a P-N junction semiconductor layer 72, such as AlGaAs and InGaP, that may absorb the medium wavelength being stacked;

further a formed P-N junction semiconductor layers 80 of Ga, In, Al an N that may absorb long wavelength, and its transparent substrate 81 of Al₂O₃ sapphire, silicon carbide, or ZnO;

in the Flip-Chip technology, the P-N junction semiconductor layers 80 of Ga, In, Al an N that may absorb short wavelength being stacked onto the P-N junction semiconductor layer 72 that may absorb medium wavelength;

The series of materials of the P-N junction semiconductor layers 80 of Ga, In, Al an N that may absorb long wavelength and those of the P-N junction semiconductor layers 72 that may absorb medium wavelength being different so that connection bumps 20 may be formed between the two P-N junction semiconductor layers and the two P-N junction semiconductor layers of different materials are combined together in the form of Flip Chip.

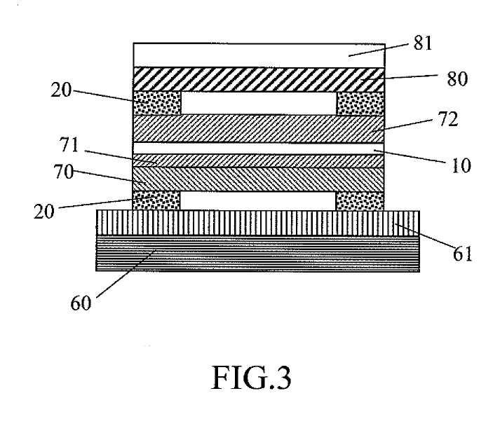

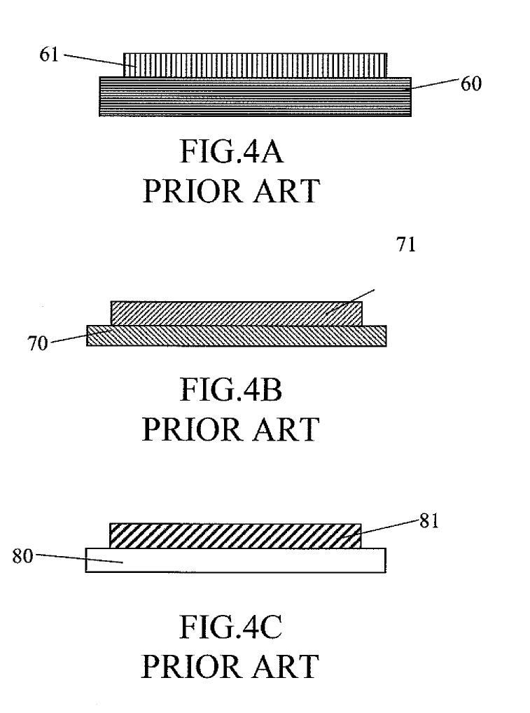

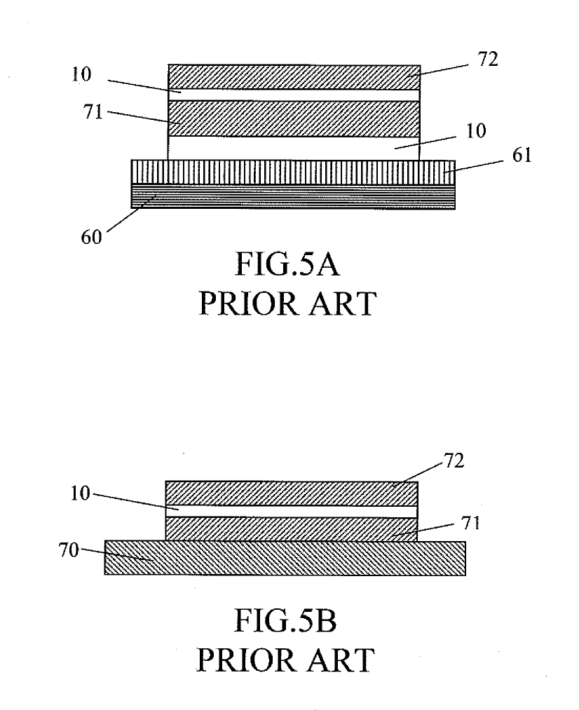

Refer to FIG. 3 illustrating:

a formed P-N junction semiconductor layers 61 of Si and Ge, such as Si and Si/Ge, that may absorb long wavelength;

formed P-N junction semiconductor layers 71 and 72 of As, Ga, and P, such as GaAs/AlGaAs, GaAs/InGaP, GaP/GaP, GaAs/AlIn GaP, and GaAs/AlGaAs . . . etc, that may absorb medium wavelength; and

a P-N junction semiconductor layers 80, such as GaN/AlGaN, GaN/InGaN and InGaN/AlGaN, that may absorb short wavelength;

in the Flip-Chip technology, the P-N junction semiconductor layers 71 and 72 that may absorb medium wavelength and the P-N junction semiconductor layers 80 that may absorb short wavelength being stacked in order onto the P-N junction semiconductor layers 61 of Si and Ge that may absorb long wavelength;

The series of materials of the P-N junction semiconductor layers 61 of Si and Ge that may absorb long wavelength, those of the P-N junction semiconductor layers 71 and 72 of As, Ga, and P that may absorb medium wavelength, and those of the P-N junction semiconductor layers of Ga, In, Al an N that may absorb short wavelength being different so that connection bumps 20 may be formed between the P-N junction semiconductor layers and the P-N junction semiconductor layers of different materials are combined together in the form of Flip Chip.

In FIGS. 2A through 2D and FIG. 3, it is more convenient and easier made to be electrically conductive to connect a chip with the bumps 20 in the Flip-Chip technology than the way of connecting a conventional solar cell with a tunnel junction. Thus, the materials that may absorb the long, medium, and short wavelength are better in efficient, and solve the problem of lattice mismatch. Further, in this invention, a lens (not shown) may be arranged on the solar cell to concentrate the beams of light so that the area of solar cell under the lens may be reduced, and further the cost of solar cell according to this invention may be down.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of hybrid stacked Flip Chip for a solar cell onto which at least another P-N junction semiconductor layers and is stacked in the Flip-Chip technology.

2. The method of hybrid stacked Flip Chip for the solar cell according to claim 1, wherein a P-N junction semiconductor layers of Si, Ge and SiGe that may absorb long wavelength is adopted.

3. The method of hybrid stacked Flip Chip for the solar cell according to claim 1, wherein a P-N junction semiconductor layer of Al, Ga, In, As and P that may absorb medium wavelength is adopted.

4. The method of hybrid stacked Flip Chip for the solar cell according to claim 1, wherein the P-N junction semiconductor layers may be stacked in order from long wavelength to short wavelength.

5. The method of hybrid stacked Flip Chip for the solar cell according to claim 1, wherein the P-N junction semiconductor layer of Si and Ge that may absorb long wavelength is first used as a substrate and a solar cell that of Ga, In, Al an N that may absorb short wavelength is then stacked.

6. The method of hybrid stacked Flip Chip for the solar cell according to claim 1, wherein the P-N junction semiconductor layer of As and P that may absorb medium wavelength is first used as a substrate, that of Ga, In, Al an N that may absorb short wavelength is then stacked.

7. The method of hybrid stacked Flip Chip for the solar cell according to claim 1, wherein the P-N junction semiconductor layer that may absorb long wavelength is first used as a substrate, that of As and P that may absorb medium wavelength is then flip chip stacked in which a tunnel junction layer is formed between those As and P related P-N junction semiconductor layers, in order to increase the conductivity of those P-N junction semiconductor layers connected in series.

8. The method of hybrid stacked Flip Chip for the solar cell according to claim 1, wherein the P-N junction semiconductor layer that may absorb long wavelength is used as a substrate, that of As and P that may absorb medium wavelength is then flip chip stacked, that of Ga, In, Al an N that may absorb short wavelength is then final flip chip stacked.
